(19) United States
(12) Patent Application Publication
(10) Pub. No.: US 2025/0072134 A1
(43) Pub. Date: Feb. 27, 2025

(54) Electronic Devices Having Compact Optical Modules

(71) Applicant: Apple Inc., Cupertino, CA (US)

(72) Inventors: Dong Zheng, Los Altos, CA (US); Kenneth J. Vampola, Los Altos, CA (US); Seshasayee Gaddamraja, Santa Clara, CA (US); Emma C. Thomson, San Jose, CA (US)

(21) Appl. No.: 18/767,001

(22) Filed: Jul. 9, 2024

Related U.S. Application Data
(60) Provisional application No. 63/520,848, filed on Aug. 21, 2023.

(51) Int. Cl. H01L 27/146

(52) U.S. Cl. CPC H01L 27/14645; H01L 27/14621; H01L 27/14625; H01L 27/14636

(57) ABSTRACT

Ambient light sensor modules may be formed using a wafer-level process in which a filter and a diffuser are stacked on a silicon substrate or a combination substrate that includes multiple photosensors. The stack may be diced, filled with opaque material, and diced again to form multiple ambient light sensor modules. The resulting modules may include a silicon substrate with a photosensor and through-silicon vias, a filter on the silicon substrate, and a diffuser coupled to the filter. There may be an air gap between a portion of the diffuser and the photosensor. The air gap may be formed from a recess in the diffuser or from spacers between the filter and the diffuser. Alternatively, the diffuser may be applied as a coating on the filter. By forming the ambient light sensor modules at the wafer level, the modules may have smaller footprints and/or volumes.

This application claims the benefit of U.S. provisional patent application No. 63/520,848, filed Aug. 21, 2023, which is hereby incorporated by reference herein in its entirety.

### FIELD

This relates generally to electronic devices, and, more particularly, to electronic devices with light sensors.

### BACKGROUND

Electronic devices such as laptop computers, cellular telephones, and other equipment are sometimes provided with light sensors. For example, ambient light sensors may be incorporated into a device to provide the device with information on current lighting conditions. Ambient light readings may be used in controlling the device. If, for example bright daylight conditions are detected, an electronic device may increase display brightness to compensate. Color ambient light sensors can detect changes in the color of ambient light so that compensating color cast adjustments can be made to displayed content.

### SUMMARY

An electronic device may have a display with an array of pixels forming an active display area. During operation of the device, the array of pixels may be used to display an image for the user. In an inactive border area or other inactive display area that is free of pixels, an opaque masking layer may be included in the display to block internal device components from view from the exterior of the electronic device. Ambient light may pass through an opening in the opaque masking layer.

The electronic device may have an ambient light sensor module aligned with the opening in the opaque masking layer. Control circuitry in the electronic device may adjust a brightness level associated with an image being displayed by the display based on ambient light measurements from the ambient light sensor module.

Ambient lights sensor modules may be formed using a wafer-level process in which a filter and a diffuser are stacked on a silicon substrate or a combination substrate that includes multiple photosensors. The stack may be diced, filled with opaque material, and diced again to form multiple ambient light sensor modules.

The resulting ambient light sensor modules may include a silicon substrate with a photosensor and through-silicon vias, a filter on the silicon substrate, a diffuser coupled to the filter, and solder bumps on the opposite side of the silicon substrate. There may be an air gap between a portion of the diffuser and the photosensor. The air gap may be formed from a recess in the diffuser or from spacers between the filter and the diffuser. Alternatively, the diffuser may be applied as a coating on the filter.

By forming the ambient light sensor modules at the wafer level, the modules may have smaller footprints and/or volumes.

### BRIEF DESCRIPTION OF THE DRAWINGS

FIG. 1 is a schematic diagram of an illustrative electronic device having an ambient light sensor module in accordance with some embodiments.

FIGS. 2 and 3 are perspective views of illustrative electronic devices in accordance with some embodiments.

FIG. 4 is a side views of illustrative ambient light sensor modules under a clear aperture in opaque masking layers in displays in accordance with embodiments.

FIG. 5 is a diagram of illustrative steps that may be used to form an ambient light sensor module in accordance with some embodiments.

FIG. 6 is a side view of an illustrative ambient light sensor module having opaque material on side surfaces and a rear surface of the module in accordance with some embodiments.

FIG. 7 is a side view of an illustrative ambient light sensor module having a bulk diffuser coating in accordance with some embodiments.

FIG. 8 is a side view of an illustrative ambient light sensor module having an air gap formed from a recess in a diffuser between the diffuser and a filter in accordance with some embodiments.

FIG. 9 is a side view of an illustrative ambient light sensor module having an air gap formed from spacers between a diffuser and a filter in accordance with some embodiments.

FIG. 10 is a side view of an illustrative ambient light sensor module having an air gap formed from spacers and opaque material between a diffuser and a filter in accordance with some embodiments.

FIG. 11 is a diagram of illustrative steps that may be used to form an ambient light sensor module using a combination substrate in accordance with some embodiments.

FIG. 12 is a side view of an illustrative ambient light sensor module with a combination substrate in accordance with some embodiments.

### DETAILED DESCRIPTION

Electronic devices, such as cellular telephones, computers (e.g., laptop computers), tablets, and wearable devices (e.g., wristwatch devices or head-mounted devices), may include optical sensors, such as ambient light sensors. The ambient light sensors may produce signals in response to ambient light, thereby indicating the ambient brightness of a device's surroundings. In some examples, the ambient brightness may be used to adjust the brightness of a display.

However, it may be desirable to reduce the size of the ambient light sensors in electronic devices. Therefore, the ambient light sensors may be formed from ambient light sensor modules that are formed at a wafer level, rather than using diced parts. For example, a silicon layer that includes vias and photosensors may be provided, and a filter and a diffuser may be provided over the silicon layer to form a stack. Solder bumps may be coupled to the back of the silicon layer. The stack may be diced and back-filled with opaque material between each of the photosensors. The stack may be diced again to separate stack into individual ambient light sensor modules.

In some embodiments, additional opaque material may be provided at the bottom of the silicon layer, in addition to the sides of the ambient light sensor module. The diffuser may be provided as a glass layer, or as a diffuser coating. If the diffuser is provided as a glass layer, the glass layer may be patterned/etched to form air gaps that diffuse light incident on the ambient light sensor module.

Regardless of the layers used in forming the ambient light sensor module, the module may be a small package, reducing the volume required to incorporate the module into an electronic device.

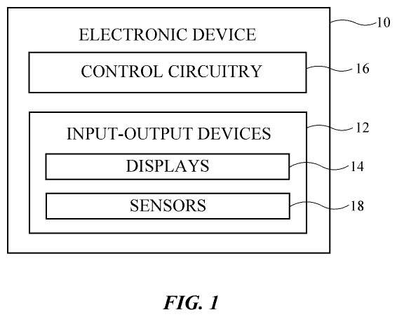

An illustrative electronic device of the type that may be provided with one or more ambient light sensor modules is shown in FIG. 1. Electronic device 10 of FIG. 1 may be a computing device such as a laptop computer, a computer monitor containing an embedded computer, a tablet computer, a cellular telephone, a media player, or other handheld or portable electronic device, a smaller device such as a wristwatch or other device worn on a user's wrist, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid-state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc. Control circuitry 16 may include communications circuitry for supporting wired and/or wireless communications between device 10 and external equipment. For example, control circuitry 16 may include wireless communications circuitry such as cellular telephone communications circuitry and wireless local area network communications circuitry.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Input-output devices 12 may also include sensors 18. Sensors 18 may include a capacitive sensor, a light-based proximity sensor, a magnetic sensor, an accelerometer, a force sensor, a touch sensor, a temperature sensor, a pressure sensor, a compass, a microphone, a radio-frequency sensor, a three-dimensional image sensor, a camera, a light-based position sensor (e.g., a lidar sensor), and other sensors. Sensors 18 may also include one or more light detectors that are configured to detect ambient light (referred to as ambient light sensors herein). Sensors 18 may, for example, include one or more monochrome ambient light sensors and one or more color ambient light sensors that are configured to measure ambient light from the environment in which device 10 is operated. A monochrome ambient light sensor may be used to measure ambient light intensity. A color ambient light sensor may be used to measure the color (color spectrum, color temperature, color coordinates, etc.) of ambient light and may be used to measure ambient light intensity.

To make color measurements, a color ambient light sensor in device 10 may have a light detector such as a photodiode that is overlapped by a tunable wavelength filter and/or may have multiple channels each of which has a light detector such as a photodiode that is overlapped by a filter that passes a different color of light (e.g., a different wavelength band) to that light detector. Photodetectors such as photodiodes may be formed in a semiconductor die. By processing the readings from each of the multiple channels, the relative intensity of each of the different colors of light can be determined. Using data from the different channels in a color ambient light sensor, control circuitry 16 can therefore produce ambient light color temperature measurements and other color measurements (e.g., colors represented in color coordinates, etc.). The ambient light color information may be used in controlling display 14 and/or in taking other actions in device 10. As an example, the color cast of images displayed on display 14 can be adjusted based on ambient light color measurements (e.g., to make the images on display 14 yellower in warm ambient lighting conditions and to make the images on display 14 bluer in cold ambient lighting conditions). If desired, display brightness may be automatically increased by control circuitry 16 in response to detection of bright ambient light conditions and may be automatically decreased by control circuitry 16 in response to detection of dim ambient light conditions. Adjustments to the brightness of the image on display 14 in this way based on ambient light sensor measurements from an ambient light sensor in device 10 may help enhance user comfort when viewing images.

Electronic device 10 may include one or more ambient light sensors. Illustrative arrangements in which device 10 includes a single ambient light sensor are sometimes described herein as an example. In some configurations, the ambient light sensor may be located directly under or nearly under display 14 (e.g., under an active display area or under an inactive border of a display, in an inactive notch formed along an edge of an active display area, in an inactive island that forms a window area within an active display area, etc.). Alternatively, the ambient light sensor may be located in an inactive area of display 14 (e.g., a peripheral area adjacent to display 14 that does not include any pixels) or on another portion of device 10.

Display 14 may be an organic light-emitting diode display, a liquid crystal display, microLED display, or other display. In some configurations, organic light-emitting diode pixel light emission or backlight unit light emission in a backlit liquid crystal display may be temporarily dimmed to help prevent backlight leakage that could generate stray light. This may help reduce noise during ambient light measurements. Ambient light measurements can also be gathered while a display backlight is active. To help reduce crosstalk while a backlight is active, an ambient light sensor module may be provided with a light attenuator. The light attenuator may attenuate stray light to help reduce stray light noise. The light attenuator may also help provide the ambient light sensor module with a dark outward appearance that matches surrounding opaque masking material that is used in the inactive area of the display. A clear aperture may be formed in an opaque masking layer to allow ambient light to reach the ambient light sensor module.

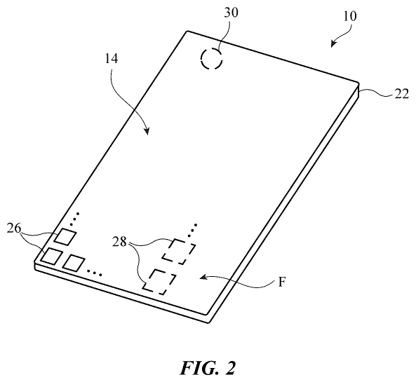

A perspective view of an illustrative electronic device of the type that may include an ambient light sensor is shown in FIG. 2. In the example of FIG. 2, device 10 includes a display such as display 14 mounted in housing 22. Display 14 may be a liquid crystal display, a light-emitting diode display such as an organic light-emitting diode display or a display formed from crystalline semiconductor light-emitting diode dies, or other suitable display. Display 14 may have an array of pixels 26 extending across some or all of front face F of device 10 and/or other external device surfaces. The pixel array may be rectangular or may have other suitable shapes. Display 14 may be protected using a display cover layer (e.g., a transparent front housing layer) such as a layer of transparent glass, clear plastic, sapphire, or other clear layer. The display cover layer may overlap the array of pixels 26.

Housing 22, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 22 and display 14 may separate an interior region of device 10 from an exterior region surrounding device 10. Housing 22 may be formed using a unibody configuration in which some or all of housing 22 is machined or molded as a single structure or may be formed using multiple structures (e.g., an internal frame structure, one or more structures that form exterior housing surfaces, etc.). If desired, a wristband or other strap may be coupled to a main portion of housing 22 (e.g., in configurations in which device 10 is a wristwatch). Internal electrical components 28 (e.g., integrated circuits, discrete components, etc.) for forming control circuitry 16 and input-output devices 12 may be mounted in the interior of housing 22. In some configurations, components 28 may be attached to display 14 (e.g., display driver circuitry may be mounted to the inner surface of display 14).

Pixels 26 may cover all of the front face F of device 10 or display 14 may have inactive areas (e.g., notches, rectangular islands, or other regions) that are free of pixels 26. The inactive areas may be used to accommodate an opening for a speaker and windows for optical components such as image sensors, an ambient light sensor, an optical proximity sensor, a three-dimensional image sensor such as a structured light three-dimensional image sensor, a camera flash, etc. An ambient light sensor may be formed under a window opening in housing 22 (e.g., a sensor may be mounted under a hole in a metal housing wall), may be formed under the active area of display 14, or may be formed under an inactive display area. For example, an ambient light sensor may be formed on front face F along one of the edges of device 10 such as illustrative ambient light sensor region 30 of FIG. 2.

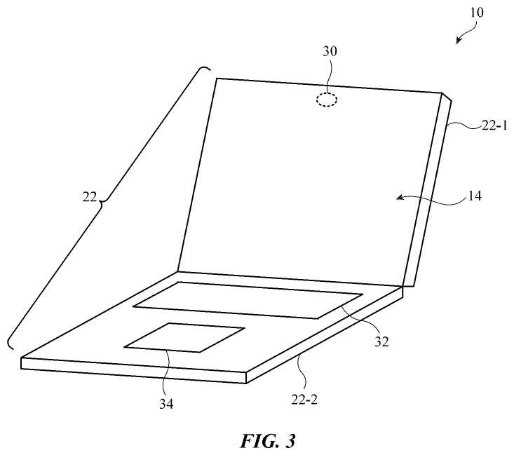

Device 10 of FIG. 2 may be a cellular telephone, tablet computer, wristwatch, or other portable device (as examples). If desired, ambient light sensors may be provided in other electronic equipment. In the example of FIG. 3, device 10 is a laptop computer. Housing 22 of device 10 of FIG. 3 includes upper housing portion 22-1 and lower housing portion 22-2, which are joined by a hinge to allow these portions to rotate with respect to each other. Display 14 may be mounted in upper housing portion 22-1. Keyboard 32 and trackpad 34 may be mounted in lower housing portion 22-2. Ambient light sensors may be mounted on housing 22 facing the exterior of device 10. As an example, an ambient light sensor module may be mounted under an active area of display 14 that is configured to display an image or an inactive area of display 14 (see, e.g., illustrative ambient light sensor region 30).

To help hide internal components in the interior of housing 22 from view, the inactive area of display 14 may be provided with an opaque masking layer. The opaque masking layer may be any suitable color (e.g., black, gray, white, a non-neutral color such as blue, etc.). In an illustrative example, display 14 has an inactive area with an opaque masking layer formed from black ink. Other opaque materials may be used, if desired.

To permit light to reach an ambient light sensor in region 30, an opening (e.g., a clear aperture, sometimes referred to as an ambient light sensor window or ambient light sensor opening) may be formed in the opaque masking layer in region 30. The shape of region 30 (e.g., the outline of the opaque masking layer opening when viewed from the exterior of device 10) may be circular, rectangular, or may have other suitable shapes. The opening may be completely free of opaque masking material (e.g., the opening may be a circular hole, etc.), thereby allowing close to 100% of ambient light to pass through the opening (e.g., at least 95% or other suitable amount of light). In the interior of device 10, an ambient light sensor module may be aligned with the ambient light sensor aperture in the opaque masking layer. To enhance the uniform appearance of the inactive area of display 14 and prevent the ambient light sensor opening from being overly noticeable to a user of device 10, the ambient light sensor module that is mounted under the opening may be provided with a light attenuator (e.g., a visible-light-absorbing structure with a light transmission of about 2-16%, at least 3%, 5-10%, 8%, at least 4%, at least 6%, less than 20%, less than 10%, or other suitable light transmission value). The dark appearance of the light attenuator in the ambient light sensor module may help absorb ambient light and reduce ambient light reflections to make the ambient light sensor module visually blend with adjacent portions of the opaque masking layer.

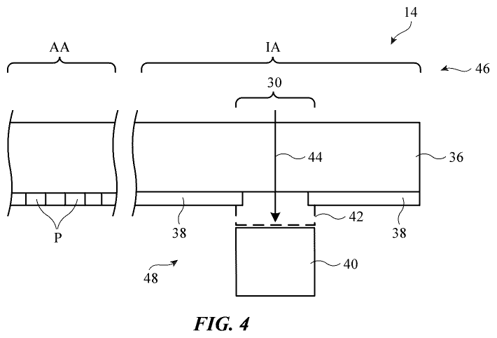

FIG. 4 is a side view of illustrative display with an ambient light sensor. Display 14 of FIG. 4 has an active area AA that displays images and an inactive area IA that is covered with opaque masking material and does not display images.

In the example of FIG. 4, display 14 has a transparent display cover layer such as display cover layer 36. Display cover layer 36 may be formed from glass, polymer, sapphire or other crystalline materials, and/or other transparent materials. In active area AA, display 14 has an array of pixels P for displaying an image. Pixels P may, for example, form a light-emitting diode display panel such as a thin-film organic light-emitting diode display panel or a display panel having a pixel array formed from crystalline semiconductor light-emitting diode dies (as examples). Configurations in which display 14 is a liquid crystal display may also be used. As shown in FIG. 4, in inactive area IA of display 14, pixels P are not present. Opaque masking layer 38 may be formed on the underside (inner surface) of display cover layer 36 in inactive area IA to hide internal components in interior region 48 from view from a user in the external environment (exterior region 46) surrounding device 10.

Ambient light sensor module 40 (also referred to as optical module 40 herein) may be mounted in alignment with an opening in opaque masking layer 38 in ambient light sensor region 30. This allows ambient light sensor module 40 to receive and measure ambient light 44 that passes through display cover layer 36 and the opening in layer 38 within ambient light sensor region 30. If desired, a layer of clear adhesive such as adhesive layer 42 may be used to attach ambient light sensor module 40 to the interior of display cover layer 38 over the opening in layer 38. Other mounting arrangements may be used, if desired.

Although FIG. 4 shows ambient light sensor module 40 in inactive area IA of display 14, this is merely illustrative. In some embodiments, ambient light sensor module 40 may be in active area AA of display 14. Alternatively, ambient light sensor module 40 may be formed in another region of device 10, such as on a sidewall or rear face of the housing of device 10.

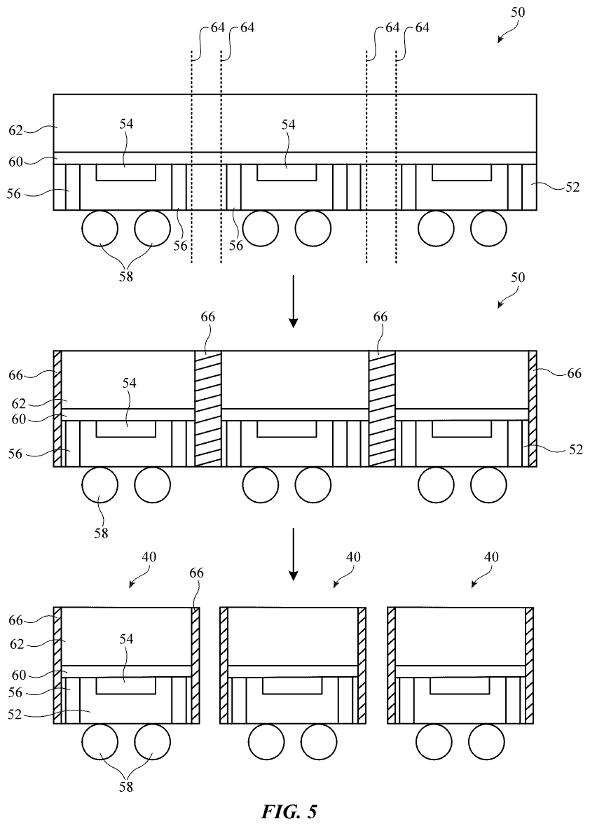

Regardless of where ambient light sensor module 40 is included in an electronic device, it may be desirable to form ambient light sensor module 40 with a small volume to reduce the space it takes up in the electronic device. An illustrative example of a process that may be used to form an ambient light sensor module is shown in FIG. 5.

As shown in FIG. 5, filter 60 and diffuser 62 may be stacked on silicon wafer 52 (also referred to as silicon 52 and silicon substrate 52 herein) to form stack 50. Silicon substrate 52 may include photosensors 54, which may include photosensitive elements, such as photodiodes, that generate charge/signals in response to incident light. Silicon substrate 52 may also include through-silicon vias (TSVs) 56 and solder bumps 58 that couple photosensors 54 to circuitry within an electronic device, such as device 10 (e.g., when a resulting ambient light sensor module is installed in the electronic device). Together, silicon substrate 52, filter 60, diffuser 62, and solder bumps 58 may form stack 50. Stack 50 may include an array of ambient light sensor photosensors 54 and therefore an array of ambient light sensor modules.

Silicon substrate 52 may have a thickness of approximately 100 microns, at least 40 microns, between 40 microns and 250 microns, or other suitable thickness. By having a thin silicon substrate 52, TSVs 56 may be etched through substrate 52 more easily.

Filter 60 may be a spectral filter, such as a thin-film interference filter. In particular, filter 60 may include dielectric layers with alternating high and low indexes of refraction (e.g., alternating first and second indexes of refraction, with the first indexes of refraction higher than the second indexes of refraction) that provide destructive interference and filter out undesired wavelengths of light. Alternatively, filter 60 may be an absorption-based filter that includes material, such as a metal material (e.g., silver) or a metal-organic hybrid material, or an organic dye that absorbs a desired wavelength of light. Regardless of the type of filter 60 used, filter 60 may ensure that certain wavelengths of light pass through to photosensor 54. For example, filter 60 may filter out infrared light by blocking or reflecting infrared light. Alternatively or additionally, filter 60 may filter out ultraviolet light or may filter out visible light of one or more wavelengths that is not desired to be detected by the underlying photosensor 54. In other words, filter 60 is used to control which wavelengths of light are measured/detected by photosensor 54.

Diffuser 62 may be a surface diffuser or a bulk diffuser. In other words, diffuser 62 may have surface texture or features to diffuse light that passes through diffuser 62, or diffuser 62 may have embedded scattering centers that diffuse the light, respectively. In an illustrative example, diffuser 62 may include a transparent substrate, such as a glass layer, a sapphire layer, a polycarbonate layer, a polymer layer, or other suitable transparent layer, that has surface texture. For example, a diffusive coating (e.g., a coating with texture) may be applied to a surface of the transparent substrate. In general, however, any suitable type of diffuser may be used.

Diffuser 62 may have a thickness of 30 microns, at least 200 microns, at least 150 microns, between 150 microns and 250 microns, between 15 microns and 300 microns, at least 20 microns, at least 50 microns, approximately 100 microns, 200 microns, or other suitable thickness. In some embodiments, for example, diffuser 62 may be formed from a glass substrate (or a substrate of other transparent material) and a diffuser coating on the transparent substrate. The glass substrate may have a thickness of 100 microns, at least 50 microns, at least 25 microns, at least 100 microns, or other suitable thickness. The diffuser coating may have a thickness of 30 microns, at least 15 microns, between 15 microns and 40 microns, or other suitable thickness.

Once stack 50 is formed by stacking silicon substrate 52, filter 60, and diffuser 62, stack 50 may be diced along cut lines 64 (e.g., between each ambient light sensor module of the array of ambient light sensor modules formed by stack 50).

Opaque material 66 may then be used to backfill the openings between cut lines 64, as well as to coat the edges of stack 50. In other words, opaque material 66 may fill regions between each of the ambient light sensor modules in stack 50. Opaque material 66 may be a black mold material (e.g., polymer), an epoxy resin (e.g., a black epoxy resin), a carbon layer, black ink, light-absorbing ink of another color, or other opaque material.

After opaque material 66 has been added, stack 50 may be diced again within opaque material 66 to form ambient light sensor modules 40. Each ambient light sensor module 40 may include silicon substrate 52, photosensor 54, TSVs 56, solder bumps 58, filter 60, diffuser 62, and opaque sidewalls 66. Although FIG. 5 shows two opaque sidewalls on each ambient light sensor module 40, each optical module 40 may also have opaque sidewalls on the two sides perpendicular to the sidewalls shown in FIG. 5. In general, each optical module 40 may have opaque material 66 on any suitable number of sidewall(s).

In this way, multiple ambient light sensor modules 40 may be formed from a single stack 50 (e.g., a single stack formed on a single wafer 52). In some embodiments, at least 2 ambient light sensor modules 40, at least 10 ambient light sensor modules 40, at least 100 ambient light sensor modules 40, at least 1,000 ambient light sensor modules 40, at least 2,000 ambient light sensor modules 40, at least 3,000 ambient light sensor modules 40, at least 5,000 ambient light sensor modules, at least 10,000 ambient light sensor modules 40, or other desired number of ambient light sensor modules 40 may be formed on a single wafer.

In operation, incident light may pass through diffuser 62 of a single ambient light sensor module 40, where the light may be diffused. The diffused light may pass through filter 60, which may filter out undesirable wavelengths of light. The remaining light may reach photosensor 54, which may generate charge/signals in response to the light. Ambient light sensor module 40 may be coupled to circuitry within device 10, such as control circuitry, via solder bumps 58 and TSVs 56, and the measurements from photosensor 54 may be read out to the circuitry within device 10 as ambient light sensor measurements. Opaque sidewalls 66 may block off-axis light, which may reduce ambient light sensor measurements of stray light.

By forming ambient light sensor module 40 using a wafer-level process (e.g., a process that forms multiple ambient light sensor modules using a single silicon wafer), ambient light sensor module 40 may have a smaller footprint and/or overall volume than an ambient light sensor module made with individual components, such as having approximately 65% less volume, at least 50% less volume, at least 40% less volume, or other volumetric reduction as compared to sensor modules that are formed individually.

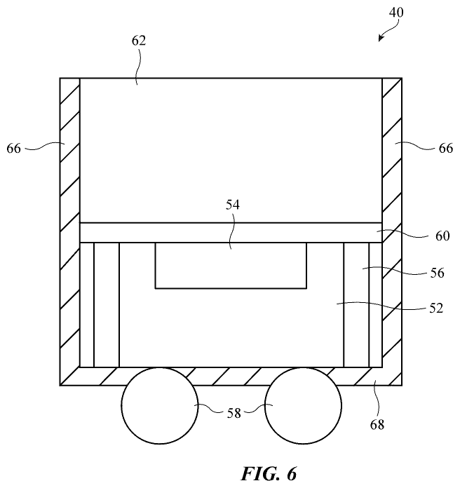

Although FIG. 5 shows opaque material 66 only on the sides of ambient light sensor module 40, this is merely illustrative. In some embodiments, it may be desirable to incorporate opaque material on other portions of ambient light sensor module 40, such as the bottom surface of ambient light sensor module 40. An illustrative example of an ambient light sensor module having opaque material on side and bottom surfaces is shown in FIG. 6.

As shown in FIG. 6, ambient light sensor module 40 may include opaque material 68 on a bottom surface of silicon substrate 52. Therefore, ambient light sensor module may have opaque material 66 on the sidewalls of the module and opaque material 68 on the bottom surface of the module. By including opaque material 68 at the bottom surface of module 40, additional light may be blocked. Additionally, sensitive components, such as the components in silicon substrate 52, may be protected when module 40 is mounted within an electronic device.

Opaque material 68 may be under-molded onto silicon substrate 52 (simultaneously with opaque material 66 on the sidewalls, if desired). Alternatively, opaque material 68 may be sprayed or spun onto the bottom surface of substrate 52. For example, silicon substrate 52 may have a cavity on the bottom surface, and opaque material 68 may be applied by either filling the cavity, or may leave a void in the cavity. In this way, the lower surface of module 40 may be coated with opaque material 68, which may block additional stray light and improve the performance of the ambient light sensor.

Opaque material 68 may be a black mold material (e.g., polymer), an epoxy resin (e.g., a black epoxy resin), a carbon layer, black ink, light-absorbing ink of another color, or other opaque material. In some embodiments, opaque material 68 may be a solder mask that allows solder bumps 58 to be formed in desired locations on the bottom surface of module 40. Alternatively or additionally, opaque material 68 may include material that blocks infrared light. For example, opaque material 68 may include metal (e.g., silver or other suitable metal) between TSVs 56 and solder bumps 58. The metal may block infrared light, reducing interference from ambient infrared light or infrared light from other components within an electronic device.

Although FIG. 6 shows opaque material 68 on the lowermost surface of module 40, this is merely illustrative. In some embodiments, opaque material may be incorporated within silicon wafer 52. For example, the surface of silicon wafer 52 may be flooded with metal, and photosensor 54 may then be mounted to silicon wafer 52. In this way, the metal may block light from reaching photosensor 54 from below module 40.

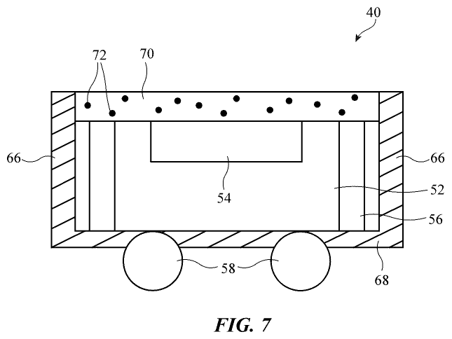

In the examples of FIGS. 5 and 6, diffuser 62 is shown as a single layer (with a coating on its surface, if desired). However, this is merely illustrative. In general, any suitable diffuser may be used in ambient light sensor module 40. An illustrative example of an ambient light sensor module having a diffuser coating applied to a silicon substrate directly is shown in FIG. 7.

As shown in FIG. 7, diffuser 70 may be a diffuser coating that is applied to the top surface of silicon substrate 52 directly. For example, diffuser 70 may be formed from epoxy, resin, polymer, or other suitable material with embedded scattering centers 72. Embedded scattering centers 72 may be formed from metal, metal oxide (e.g., titanium dioxide), polymer (e.g., a polymer with a different index of refraction from the bulk substrate of diffuser 70), or other suitable material to diffuse light that passes through diffuser 70. Diffuser 70 may be applied to filter 60 (and/or silicon substrate 52) using a one-shot (or multiple shot) process, or may be applied as a spin coating. Regardless of the process by which diffuser 70 is formed in module 40, a glass diffuser substrate (such as diffuser 62 of FIGS. 4-5) may be omitted, and a thinner diffuser coating may be used on ambient light sensor module 40. This may reduce the height of ambient light sensor module 40.

Although not shown in FIG. 7, a filter, such as filter 60 of FIGS. 5 and 6, may be incorporated in ambient light sensor module 40 between diffuser 70 and photosensor 54, if desired. Alternatively, diffuser 70 may be formed from or include filter layers that filter the light incident on module 40 before the light reaches photosensor 54.

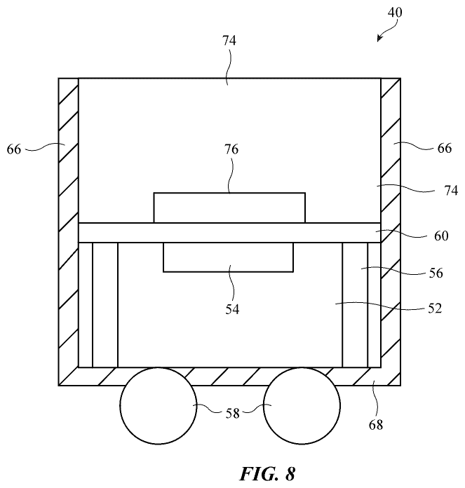

As another example of a diffuser that may be incorporated into an ambient light sensor module, FIG. 8 shows an illustrative arrangement of a diffuser with a recess that forms an air gap. In particular, as shown in FIG. 8, diffuser 74 may include a recess that forms air gap 76 over photosensor 54. The recess forming air gap 76 may be etched into diffuser 74, such as using lithography (e.g., if diffuser 74 is formed from glass or sapphire), or diffuser 74 may be formed with the recess such as by molding diffuser 74 with the recess (e.g., if diffuser 74 is formed from polymer). The regions of diffuser 74 adjacent to the recess forming air gap 76 may be directly coupled to filter 60.

Air gap 76 may allow for more flexibility in designing filter 60. In particular, air gap 76 may allow light passing through module 40 to be refracted (e.g., at the interface between diffuser 74 and air gap 76) before reaching filter 60. This may allow filter 60 to be formed from purely dielectric layers (e.g., thin-film dielectric layers with alternating indexes of refraction), as an example. Alternatively or additionally, air gap 76 may allow for robust coating materials to be provided within module 40 (e.g., on either side of air gap 76).

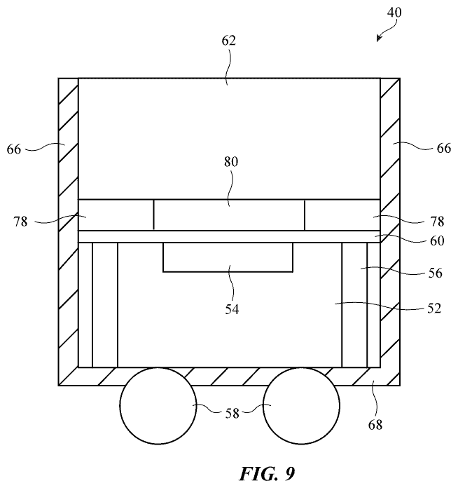

Although air gap 76 has been described as being formed from a recess in diffuser 74, this is merely illustrative. In some embodiments, an air gap may be formed by adding additional material between the diffuser and the silicon wafer. An illustrative example is shown in FIG. 9.

As shown in FIG. 9, spacers 78 may be provided between diffuser 62 and filter 60 to form air gap 80. Spacers 78 may be formed from epoxy, photoimageable resist, silicon dioxide, optically clear adhesive, or other suitable material. Air gap 80 may provide the same functionality as air gap 76 of FIG. 8.

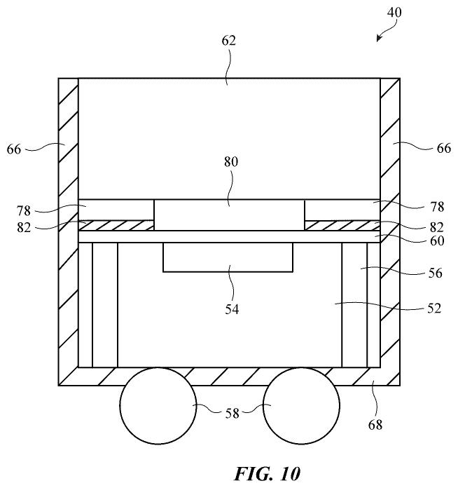

If desired, masking material may be provided on either side of air gap 80. For example, as shown in the illustrative embodiment of FIG. 10, opaque masking layers 82 may be provided between spacers 78 and filter 60. Opaque masking layers 82 may be formed from a black mold material (e.g., polymer), an epoxy resin (e.g., a black epoxy resin), a carbon layer, black ink, light-absorbing ink of another color, or other opaque material. In general, opaque masking layers 82 may prevent stray light from reaching photosensor 54 and may therefore improve the ambient light sensor measurements produced by ambient light sensor module 40.

Although modules 40 have been described as ambient light sensor modules, this is merely illustrative. In general, any suitable optical module may be formed using a wafer-level process (e.g., as shown in FIG. 5). In particular, photosensor 54 could be replaced by a sensor sensitive to other wavelengths of light, such as infrared light, ultraviolet light, etc.

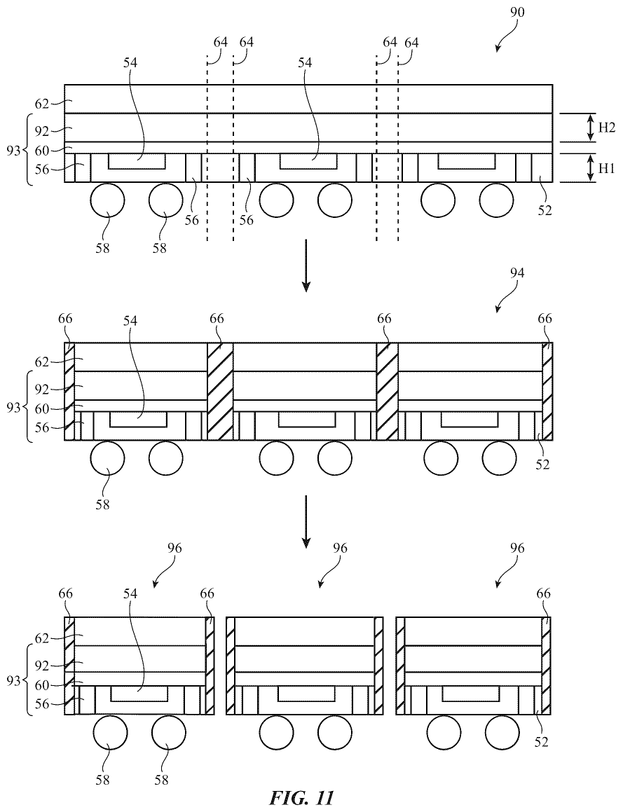

In the examples of FIGS. 5-10, optical module 40 includes silicon substrate 52. In some embodiments, it may be desirable to form an optical module using a combination substrate that uses multiple layers of different materials. An illustrative example of a process that may be used to form an ambient light sensor module with a combination substrate is shown in FIG. 11.

As shown in FIG. 11, filter 60, substrate 92, and diffuser 62 may be stacked on silicon wafer 52 (also referred to as silicon 52 and silicon substrate 52 herein) to form stack 90. Silicon substrate 52 may include photosensors 54, which may include photosensitive elements, such as photodiodes, that generate charge/signals in response to incident light. Silicon substrate 52 may also include through-silicon vias (TSVs) 56 and solder bumps 58 that couple photosensors 54 to circuitry within an electronic device, such as device 10 (e.g., when a resulting ambient light sensor module is installed in the electronic device).

Substrate 92 may be a glass substrate, ceramic substrate, sapphire substrate, and/or any other suitable substrate. Together, substrate 52 and substrate 92 may form combination substrate 93 in which filter 60 is embedded (e.g., filter 60 may be between substrate 52 and substrate 92). Silicon substrate 52 may have height H1 of at least 50 microns, at least 75 microns, at least 100 microns, between 75 microns and 125 microns, less than 200 microns, or another suitable height. Substrate 92 may have height H2 of at least 50 microns, at least 75 microns, at least 100 microns, between 75 microns and 125 microns, less than 200 microns, or another suitable height. By including substrate 92, silicon substrate 52 may be thinner, and TSVs 56 may be etched through substrate 52 more easily.

Although not shown in FIG. 11, one or more additional layers may be embedded in combination substrate 93, if desired, such as adhesive layers between substrate 52, filter 60, diffuser 62, and/or substrate 92.

Together, silicon substrate 52, filter 60, substrate 92, diffuser 62, and solder bumps 58 may form stack 90. Stack 90 may include an array of ambient light sensor photosensors 54 and therefore an array of ambient light sensor modules. Although diffuser 62 is shown as a single-layer diffuser in the example of FIG. 11, diffuser 62 may be formed from multiple layers, if desired. For example, diffuser 62 may be formed from a diffuser material mounted on a substrate (e.g., a polymer, glass, ceramic, or polycarbonate substrate), which in turn is attached to substrate 92.

Once stack 90 is formed by stacking silicon substrate 52, filter 60, substrate 92, and diffuser 62, stack 90 may be diced along cut lines 64 (e.g., between each ambient light sensor module of the array of ambient light sensor modules formed by stack 90).

Opaque material 66 may then be used to backfill the openings between cut lines 64, as well as to coat the edges of the stack to form stack 94. In other words, opaque material 66 may fill regions between each of the ambient light sensor modules in stack 94. Opaque material 66 may be a black mold material (e.g., polymer), an epoxy resin (e.g., a black epoxy resin), a carbon layer, black ink, light-absorbing ink of another color, or other opaque material.

After opaque material 66 has been added, stack 94 may be diced again within opaque material 66 to form ambient light sensor modules 96. Each ambient light sensor module 96 may include silicon substrate 52, photosensor 54, TSVs 56, solder bumps 58, filter 60, substrate 92, diffuser 62, and opaque sidewalls 66. Although FIG. 11 shows two opaque sidewalls on each ambient light sensor module 96 (also referred to as optical module 96 herein), each optical module 96 may also have opaque sidewalls on the two sides perpendicular to the sidewalls shown in FIG. 11. In general, each optical module 96 may have opaque material 66 on any suitable number of sidewall(s).

In this way, multiple ambient light sensor modules 96 may be formed from a single stack 90 (e.g., a single stack formed on a single combination substrate 93). In some embodiments, at least 2 ambient light sensor modules 96, at least 10 ambient light sensor modules 96, at least 100 ambient light sensor modules 96, at least 1,000 ambient light sensor modules 96, at least 2,000 ambient light sensor modules 96, at least 3,000 ambient light sensor modules 96, at least 5,000 ambient light sensor modules 96, at least 10,000 ambient light sensor modules 96, or other desired number of ambient light sensor 96 may be formed on a single wafer.

In operation, incident light may pass through diffuser 62 of a single ambient light sensor module 96, where the light may be diffused. The diffused light may pass through filter 60, which may filter out undesirable wavelengths of light. The remaining light may reach photosensor 54, which may generate charge/signals in response to the light. Ambient light sensor module 96 may be coupled to circuitry within device 10, such as control circuitry, via solder bumps 58 and TSVs 56, and the measurements from photosensor 54 may be read out to the circuitry within device 10 as ambient light sensor measurements. Opaque sidewalls 66 may block off-axis light, which may reduce ambient light sensor measurements of stray light.

By forming ambient light sensor module 96 using a wafer-level process (e.g., a process that forms multiple ambient light sensor modules using a single silicon wafer), ambient light sensor module 96 may have a smaller footprint and/or overall volume than an ambient light sensor module made with individual components, such as having approximately 65% less volume, at least 50% less volume, at least 40% less volume, or other volumetric reduction as compared to sensor modules that are formed individually.

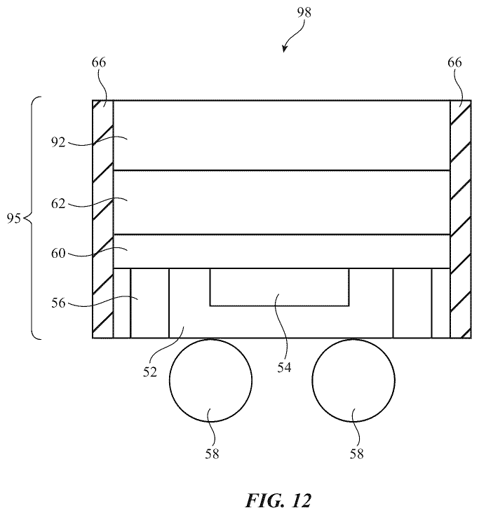

Although FIG. 11 shows substrate 92 between filter 60 and diffuser 62, this is merely illustrative. In some embodiments, diffuser 62 may be placed on top of filter 60, with substrate 92 on top of diffuser 62. In other words, diffuser 62 may be interposed between filter 60 and substrate 92. An illustrative example is shown in FIG. 12.

As shown in FIG. 12, ambient light sensor module 98 may include diffuser 62 on (e.g., directly on) filter 60 and substrate 92 on (e.g., directly on) diffuser 62. Together, substrate 52 substrate 92 may form combination substrate 95 in which filter 60 and diffuser 62 are embedded. Although not shown in FIG. 12, one or more additional layers may be embedded in combination substrate 95, if desired, such as adhesive layers between substrate 52, filter 60, diffuser 62, and/or substrate 92.

In the arrangement of FIG. 12, substrate 92 may be exposed to the exterior of ambient light sensor module 98 (or may be interposed between the exterior of ambient light sensor module 98 and diffuser 62). Because substrate 92 may be formed from glass or other suitable material that has a higher scratch resistance and/or other high durability than diffuser 62, substrate 92 may protect diffuser 62.

Although not shown in FIGS. 11 and 12, ambient light sensor module 96 with combination substrate 93 and/or ambient light sensor module 98 with combination substrate 95 may have opaque material on side and bottom surfaces (e.g., as shown in FIG. 6), may have a diffuser coating applied directly to combination substrate 93 (e.g., as shown in FIG. 7), may have a diffuser with a recess that forms an air gap (e.g., as shown in FIG. 8), may have multiple diffusers separated by an air gap (e.g., as shown in FIG. 9), and/or may include opaque masking layers and spacers between combination substrate 93 and a diffuser (e.g., as shown in FIG. 10). In this way, an ambient light sensor module may be formed with a combination substrate.

As described above, one aspect of the present technology is the gathering and use of information such as sensor information. The present disclosure contemplates that in some instances, data may be gathered that includes personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, username, password, biometric information, or any other identifying or personal information.

The present disclosure recognizes that the use of such personal information, in the present technology, can be used to the benefit of users. For example, the personal information data can be used to deliver targeted content that is of greater interest to the user. Accordingly, use of such personal information data enables users to have control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the United States, collection of or access to certain health data may be governed by federal and/or state laws, such as the Health Insurance Portability and Accountability Act (HIPAA), whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, the present technology can be configured to allow users to select to “opt in” or “opt out” of participation in the collection of personal information data during registration for services or anytime thereafter. In another example, users can select not to provide certain types of user data. In yet another example, users can select to limit the length of time user-specific data is maintained. In addition to providing “opt in” and “opt out” options, the present disclosure contemplates providing notifications relating to the access or use of personal information. For instance, a user may be notified upon downloading an application (“app”) that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of information that may include personal information data to implement one or more various disclosed embodiments, the present disclosure also contemplates that the various embodiments can also be implemented without the need for accessing personal information data. That is, the various embodiments of the present technology are not rendered inoperable due to the lack of all or a portion of such personal information data.

The foregoing is merely illustrative and various modifications can be made to the described embodiments. The foregoing embodiments may be implemented individually or in any combination.

What is claimed is:

1. An ambient light sensor module, comprising:
a silicon substrate comprising a photosensor, wherein the silicon substrate has opposing first and second surfaces;
a filter coupled to the first surface of the silicon substrate; and
a diffuser coupled to the filter.

2. The ambient light sensor module of claim 1, further comprising:
through-silicon vias that pass through the silicon substrate from the first surface to the second surface; and
solder bumps coupled to the second surface.

3. The ambient light sensor module of claim 2, wherein the diffuser comprises a transparent substrate and a diffusive coating on the transparent substrate.

4. The ambient light sensor module of claim 3, wherein the transparent substrate comprises a recess, and wherein the recess overlaps the photosensor to form an air gap between the photosensor and the diffuser.

5. The ambient light sensor module of claim 3, further comprising:
spacers interposed between the filter and the diffuser, wherein the spacers form an air gap between the filter and the diffuser.

6. The ambient light sensor module of claim 5, further comprising:
opaque masking material interposed between the spacers and the filter.

7. The ambient light sensor module of claim 3, wherein at least a portion of the transparent substrate is separated from the filter by an air gap, the portion overlaps the photosensor, the filter comprises a plurality of thin-film dielectric layers with alternating first and second indexes of refraction, and the first indexes of refraction are higher than the second indexes of refraction.

8. The ambient light sensor module of claim 2, wherein the silicon substrate has side surfaces that extend between the first and second surfaces, the ambient light sensor module further comprising:
opaque material on the side surfaces.

9. The ambient light sensor module of claim 8, wherein the opaque material is further coupled to side surfaces of the filter and the diffuser.

10. The ambient light sensor module of claim 9, further comprising:
additional opaque material on the second surface of the silicon substrate.

11. The ambient light sensor module of claim 10, wherein the additional opaque material comprises a solder mask that surrounds the solder bumps.

12. The ambient light sensor module of claim 10, wherein the additional opaque material is configured to block infrared light.

13. The ambient light sensor module of claim 12, wherein the additional opaque material comprises metal.

14. The ambient light sensor module of claim 1, wherein the diffuser comprises a bulk diffuser coating on the filter, and wherein the bulk diffuser coating comprises a plurality of scattering centers in a substrate.

15. The ambient light sensor module of claim 1, further comprising:
a glass substrate, wherein the glass substrate and the silicon substrate together form a combination substrate.

16. The ambient light sensor module of claim 15, wherein the glass substrate is interposed between the silicon substrate and the diffuser.

17. The ambient light sensor module of claim 15, wherein the diffuser is interposed between the silicon substrate and the glass substrate.

18. A method of forming an ambient light sensor module, comprising:
stacking a filter and a diffuser on a silicon wafer that includes a plurality of photosensors to form an array of ambient light sensor modules;
dicing the array of ambient light sensor modules;
filling regions between each of the ambient light sensor modules with opaque material; and
dicing the array of ambient light sensor modules within the opaque material to form individual ambient light sensor modules.

19. The method of claim 18, further comprising:
depositing additional opaque material on a rear surface of the silicon wafer.

20. The method of claim 18, wherein stacking the filter and the diffuser on the silicon wafer comprises stacking the diffuser on the filter with an air gap between a portion of the diffuser and a portion of the filter.

21. The method of claim 20, wherein stacking the diffuser on the filter with the air gap comprises stacking the diffuser on the filter with intervening spacers.

22. The method of claim 18, wherein stacking the filter and the diffuser on the silicon wafer to form an array of ambient light sensor modules comprises forming an array of at least 10 ambient light sensor modules.

23. The method of claim 18, further comprising:
stacking a glass substrate on the silicon wafer with the filter between the silicon wafer and the glass substrate.

24. An ambient light sensor module, comprising:
a silicon substrate having first and second opposing surfaces, through-silicon vias that extend from the first surface to the second surface, and a photosensor at the first surface;
solder bumps on the second surface;
a filter coupled to the first surface of the silicon substrate; and
a diffuser coupled to the filter with an air gap between the diffuser and the filter.

25. The ambient light sensor module of claim 24, wherein the diffuser comprises a transparent substrate with a recess and portions surrounding the recess, the recess overlaps the photosensor, and the portions of the transparent substrate surrounding the recess are directly coupled to the filter.

26. The ambient light sensor module of claim 24, further comprising:
spacers interposed between the diffuser and the filter that form the air gap.

27. The ambient light sensor module of claim 24, further comprising:
a glass substrate, wherein the glass substrate and the silicon substrate form a combination substrate, and wherein the filter is between the glass substrate and the silicon substrate.
